(19) United States
(12) Patent Application Publication
(10) Pub. No.: US 2025/0273950 A1
(43) Pub. Date: Aug. 28, 2025

(54) VOLTAGE LIMITER CIRCUIT, DIRECTIVE CIRCUIT, AND MEASUREMENT INSTRUMENT

(71) Applicant: Rohde & Schwarz GmbH & Co. KG, Muenchen (DE)

(72) Inventors: Thomas RABENSTEIN, Muenchen (DE); Florian HUBER, Muenchen (DE); Markus WEISS, Muenchen (DE)

(21) Appl. No.: 18/980,528

(22) Filed: Dec. 13, 2024

(30) Foreign Application Priority Data
Feb. 22, 2024 (EP) 24 159 076.9

(51) Int. Cl. H02H 9/04; G01R 13/02

(52) U.S. Cl. CPC H02H 9/04; G01R 13/0218

(57) ABSTRACT

A voltage limiter circuit for limiting a voltage applied to an electronic structure is described. The voltage limiter circuit includes a first port being connectable to a device under test. The voltage limiter circuit further includes a second port being connectable to the electronic structure. The voltage limiter circuit includes a transmission line connecting the first port and the second port. The voltage limiter circuit includes a positive voltage limiter unit that is configured to limit a positive voltage portion on the transmission line to a threshold. The voltage limiter circuit further includes a negative voltage limiter unit that is configured to limit a negative voltage portion on the transmission line to a threshold. Further, a directive circuit and a measurement instrument are described.

### CROSS-REFERENCE TO RELATED APPLICATION

This application claims priority from European Application No. 24 159 076.9, filed on Feb. 22, 2024, the entire disclosure of which is incorporated herein in its entirety.

### FIELD OF THE DISCLOSURE

Embodiments of the present disclosure generally relate to a voltage limiter circuit for limiting a voltage applied to an electronic structure. Embodiments of the present disclosure further relate to a directive circuit and to a measurement instrument.

### BACKGROUND

As is well-known in the state of the art, certain types of electronic structures need to be protected from overvoltages, for example from overvoltages due to electrostatic discharges, in order to avoid damages to the electronic structure.

Therein, it is desirable that the corresponding voltage limiter structures limiting the voltage applied to the electronic structure impair the functionality of the electronic structure as little as possible.

For example, voltage limiter structures used in measurement instruments should be configured such that impairments of the bandwidth of the measurement instrument are kept to a minimum.

Thus, there is a need for a voltage limiter circuit, a directive circuit, and a measurement instrument that allow for a reliable overvoltage protection and a high bandwidth.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a voltage limiter circuit for limiting a voltage applied to an electronic structure. In an embodiment, the voltage limiter circuit comprises a first port being connectable to a device under test and a second port being connectable to the electronic structure. The voltage limiter circuit comprises a transmission line connecting the first port and the second port. The voltage limiter circuit comprises a positive voltage limiter unit comprising circuitry configured to limit a positive voltage portion on the transmission line to a threshold. The voltage limiter circuit further comprises a negative voltage limiter unit comprising circuitry configured to limit a negative voltage portion on the transmission line to a threshold.

According to the present disclosure two types of different voltage limiter units are provided that are connected to the transmission line connecting the first port and the second port, namely the positive voltage limiter unit and the negative voltage limiter unit. These two types of different voltage limiter units ensure that neither positive nor negative overvoltages damage an electronic structure that is connected to the second port.

The inventors have recognized that the voltage limiter circuit disclosed herein is suitable for protecting the electronic structure connected to the second port in a wide frequency range from direct current, i.e. 0 Hz, up to for example 54 GHz.

In an embodiment, the voltage limiter circuit reliably protects the electronic structure connected to the second port from electrostatic discharges up to about 8 kV.

According to an aspect of the present disclosure, the transmission line comprises, for example, a plurality of transmission line sections. In an embodiment, the neighboring transmission line sections have different impedances, for example wherein the neighboring transmission line sections have different widths. In other words, the impedance, for example the width, of the transmission line is alternating between different values along the path from the first port to the second port. In an embodiment, the transmission line may comprise a plurality of transmission line sections having larger impedance, for example smaller width, and a plurality of transmission line sections having smaller impedance, for example greater width. It has turned out that transmission characteristics of the voltage limiter circuit are enhanced over the relevant frequency spectrum due to the plurality of transmission line sections having different impedances. More precisely, it has turned out that resonance modes in the transmission characteristics are flattened.

In an embodiment, the different impedances of the neighboring transmission line sections may be caused by the neighboring transmission line sections having different widths, wherein a smaller width corresponds to a larger impedance and vice versa.

In an embodiment, each transmission line section may have one of two different impedances, for example one of two different widths.

In an embodiment, the transmission line sections may comprise a first type of transmission line sections and a second type of transmission line sections, wherein the impedance of the first type of transmission line sections is smaller than a first predefined impedance threshold, and wherein the impedance of the second type of transmission line sections is larger than a second predefined impedance threshold.

In other words, the width of the first type of transmission line sections may be greater than a first predefined width threshold, and the width of the second type of transmission line sections may be smaller than a second predefined width threshold.

In an embodiment, the first predefined impedance threshold and the second predefined impedance threshold may be equal to each other. Alternatively, the first predefined impedance threshold may be smaller than the second predefined impedance threshold.

Likewise, the first predefined width threshold and the second predefined width threshold may be equal to each other. Alternatively, the first predefined width threshold may be greater than the second predefined width threshold.

Therein and in the following, the term “width” is understood to denote a dimension of the transmission line sections that is perpendicular to the axial direction of the transmission line extending between the first port and the second port and that is parallel to a substrate on which the transmission line is provided.

In an embodiment, the transmission line sections may have a pairwise equal thickness. In an embodiment, the thickness of the transmission line may be constant between the first port and the second port.

In an embodiment, all transmission line sections with a smaller impedance compared to neighboring transmission line sections have the same impedance, and/or wherein all transmission line sections with a larger impedance compared to neighboring transmission line sections have the same impedance. It has turned out that the transmission characteristics of the voltage limiter circuit can be further enhanced over the relevant frequency spectrum by choosing the same impedance, for example the same width, for the transmission line sections having smaller impedance and/or by choosing the same impedance, for example the same width, for the transmission line sections having greater impedance.

Accordingly, in these embodiments, all transmission line sections with a smaller width compared to neighboring transmission line sections may have the same width, and/or all transmission line sections with a greater width compared to neighboring transmission line sections may have the same width.

According to another aspect of the present disclosure, the negative voltage limiter unit, for example, is connected to the transmission line sections having a smaller impedance compared to neighboring transmission line sections. In an embodiment, the negative voltage limiter unit is connected to respective centers of the transmission line sections having the smaller impedance. Thus, the negative voltage limiter unit may be connected to the transmission line sections having a greater width compared to neighboring transmission line sections, for example wherein the negative voltage limiter unit is connected to respective centers of the transmission line sections having the greater width. In general, the transmission line sections having greater width have a larger capacitance and a smaller inductance than the transmission line sections having smaller width. It has turned out that the transmission characteristics of the voltage limiting circuit can be further enhanced by connecting the negative voltage limiting unit to the transmission line sections having larger capacitance.

In another embodiment, the positive voltage limiter unit is connected to the transmission line sections having a larger impedance compared to neighboring transmission line sections. In an embodiment, the positive voltage limiter unit is connected to respective centers of the transmission line sections having the larger impedance. Thus, the positive voltage limiter unit may be connected to the transmission line sections having a smaller width compared to neighboring transmission line sections, for example wherein the positive voltage limiter unit may be connected to respective centers of the transmission line sections having the smaller width. In general, the transmission line sections having smaller width have a larger inductance and a smaller capacitance than the transmission line sections having greater width. It has turned out that the transmission characteristics of the voltage limiting circuit can be further enhanced by connecting the positive voltage limiting unit to the transmission line sections having larger inductance.

Another aspect of the present disclosure provides, for example, that the negative voltage limiter unit comprises a first set of diodes and a second set of diodes. In an embodiment, the first set of diodes is interconnected between a first reference potential and a first one of the transmission line sections having the smaller impedance, for example the greater width, and wherein the second set of diodes is interconnected between the first reference potential and a second one of the transmission line sections having the smaller impedance, for example the greater width, for example wherein the first reference potential is ground or a constant DC potential. The first set of diodes and the second set of diodes may be connected to different transmission line sections, such that contact points between the sets of diodes and the transmission line are spaced differently from the first port. It has turned out that this further enhances the transmission characteristics of the voltage limiting circuit.

If the first reference potential is the constant DC potential, the first reference potential may be a negative voltage. This may increase a linearity of the voltage limiter circuit.

In an embodiment, the first set of diodes may comprise a plurality of diodes that are serially connected with each other.

In an embodiment, the first set of diodes may comprise at least three diodes, for example four, five, six, or more diodes.

Likewise, in an embodiment, the second set of diodes may comprise a plurality of diodes that are serially connected with each other.

In an embodiment, the second set of diodes may comprise at least three diodes, for example four, five, six, or more diodes.

In an embodiment, the diodes of the first set of diodes and/or the diodes of the second set of diodes may be PIN diodes, respectively. However, it is to be understood that any other suitable type of diodes may be used.

In an embodiment, contact points between the sets of diodes of the negative voltage limiter unit and the transmission line are spaced differently from the first port. In other words, a first contact point between the first set of diodes and the transmission line may have a first distance from the first port, wherein a second contact point between the second set of diodes and the transmission line may have a second distance from the first port, wherein the first distance is different from the second distance. It has turned out that this enhances the transmission characteristics of the voltage limiting circuit even if the transmission line has a uniform width along its complete length.

In another embodiment, cathodes of the first set of diodes and of the second set of diodes are facing the transmission line. This way, negative overvoltages can be reliably avoided from damaging electronic structures connected to the second port.

According to a further aspect of the present disclosure, the first set of diodes and the second set of diodes, for example, are connected to different transmission line sections. Thus, contact points between the sets of diodes of the negative voltage limiter unit and the transmission line are spaced differently from the first port. It has turned out that this further enhances the transmission characteristics of the voltage limiting circuit.

Another aspect of the present disclosure provides, for example, that the positive voltage limiter unit comprises a first set of diodes and a second set of diodes. In an embodiment, the first set of diodes is interconnected between a second reference potential and a first one of the transmission line sections having the larger impedance, for example the smaller width, and wherein the second set of diodes is interconnected between the second reference potential and a second one of the transmission line sections having the larger impedance, for example the smaller width, for example wherein the second reference potential is ground or a constant DC potential. The first set of diodes and the second set of diodes may be connected to different transmission line sections, such that contact points between the sets of diodes and the transmission line are spaced differently from the first port. It has turned out that this further enhances the transmission characteristics of the voltage limiting circuit.

If the first reference potential is the constant DC potential, the first reference potential may be a positive voltage. This may increase a linearity of the voltage limiter circuit.

In general, the first reference potential may be equal to the second reference potential. For example, both the first reference potential and the second reference potential may be ground. However, the first reference potential and the second reference potential may also be different from each other. For example, the first reference potential may be a negative constant DC voltage, while the second reference potential may be a positive constant DC voltage.

In an embodiment, the first set of diodes may comprise a plurality of diodes that are serially connected with each other.

In an embodiment, the first set of diodes may comprise at least three diodes, for example four, five, six, or more diodes.

In an embodiment, the second set of diodes may comprise a plurality of diodes that are serially connected with each other.

In an embodiment, the second set of diodes may comprise at least three diodes, for example four, five, six, or more diodes.

In an embodiment, the diodes of the first set of diodes and/or the diodes of the second set of diodes may be PIN diodes, respectively. However, it is to be understood that any other suitable type of diodes may be used.

According to an aspect of the present disclosure, contact points between the sets of diodes of the positive voltage limiter unit and the transmission line, for example, are spaced differently from the first port. In other words, a first contact point between the first set of diodes and the transmission line may have a first distance from the first port, wherein a second contact point between the second set of diodes and the transmission line may have a second distance from the first port, wherein the first distance is different from the second distance. It has turned out that this enhances the transmission characteristics of the voltage limiting circuit even if the transmission line has a uniform width along its complete length.

In an embodiment, anodes of the first set of diodes and of the second set of diodes are facing the transmission line. This way, positive overvoltages can be reliably avoided from damaging electronic structures connected to the second port.

In an embodiment, the first set of diodes and the second set of diodes may be connected to different transmission line sections. Thus, contact points between the sets of diodes of the positive voltage limiter unit and the transmission line are spaced differently from the first port. It has turned out that this further enhances the transmission characteristics of the voltage limiting circuit.

According to an aspect of the present disclosure, the transmission line sections, for example, have equal length. In an embodiment, all transmission line sections may have equal length.

A further aspect of the present disclosure provides, for example, that the voltage limiter circuit is established as a monolithic microwave integrated circuit. Accordingly, a highly integrated voltage limiter circuit is provided. For example, the voltage limiter circuit may be provided on the same substrate as further electronic components or electronic structures that are connected to the second port.

Embodiments of the present disclosure further provide a directive circuit. In an embodiment, the directive circuit comprises a plurality of ports, wherein the plurality of ports comprise a DUT port and at least two further ports. The DUT port is connectable to a device under test. The directive circuit is configured to selectively forward signals between the plurality of ports. The DUT port comprises or is connected to any one of the voltage limiter circuits described above.

In an embodiment, the at least one further port may comprise a REF port that is connected to a reference receiver.

Alternatively or additionally, the at least one further port may comprise a GEN port, wherein the GEN port is configured to receive a signal generated by a signal generator, e.g. a vector signal generator.

Alternatively or additionally, the at least one further port may comprise at least one MEAS port, wherein the at least one MEAS port may be connected to a measurement receiver being configured to perform measurements on signals received from the at least one MEAS port.

Regarding the advantages and further properties of the directive circuit, reference is made to the explanations given above with respect to the voltage limiter circuit, which also hold for the directive circuit and vice versa.

Embodiments of the present disclosure further provide a measurement instrument, for example a vector network analyzer or a spectrum analyzer. The measurement instrument comprises any one of the voltage limiter circuits described above and/or the directive circuits described above.

Regarding the advantages and further properties of the measurement instrument, reference is made to the explanations given above with respect to the voltage limiter circuit and the directive circuit, which also hold for the measurement instrument and vice versa.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a first embodiment of a measurement instrument according to the present disclosure;

FIG. 2 schematically shows a second embodiment of a measurement instrument according to the present disclosure;

FIG. 3 schematically shows a directive circuit according to an embodiment of the present disclosure;

FIG. 4a schematically shows a portion of a negative voltage limiter unit;

FIG. 4b schematically shows a portion of a positive voltage limiter unit; and

FIG. 5 shows several plots of transmission characteristics over frequency.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

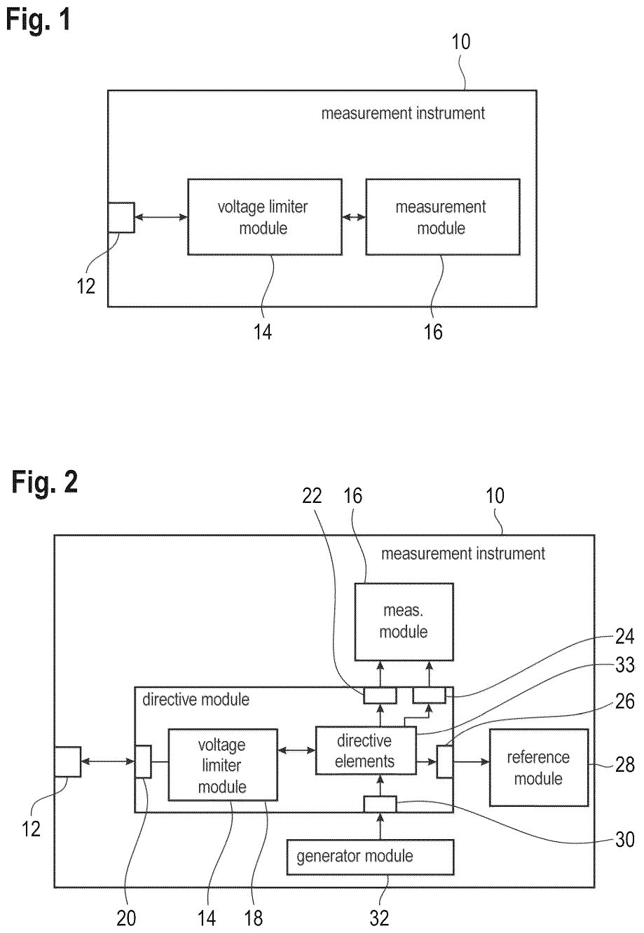

FIG. 1 schematically shows a first example embodiment of a measurement instrument 10 that is configured to perform measurements on an electronic device under test. For example, the measurement instrument 10 may be a spectrum analyzer, a signal analyzer, a vector signal analyzer, or an oscilloscope, for example a digital oscilloscope.

In the embodiment shown, the measurement instrument 10 comprises a DUT connector 12 that is configured to be connected to the electronic device under test. For example, the DUT connector 12 may be a port that is integrated into a housing of the measurement instrument 10.

In the example embodiment shown in FIG. 1, the measurement instrument 10 further comprises a voltage limiter circuit 14, and a measurement circuit 16. The voltage limiter circuit 14 is interconnected between the DUT connector 12 and the measurement circuit 16.

In general, the voltage limiter circuit 14 is configured to limit a voltage applied to electronic structures downstream of the voltage limiter circuit 14, for example to the measurement circuit 16. The voltage limiter circuit 14 is configured to forward a signal received from the device under test via the DUT connector 12 to the measurement circuit 16, while simultaneously limiting the voltage applied to the measurement circuit 16. The functionality and structure of the voltage limiter circuit 14 will be described in more detail below.

In an embodiment, the measurement circuit 16 is configured to perform measurements on the signal received from the device under test, e.g. in order to assess a performance of the device under test.

FIG. 2 shows another example embodiment of a measurement instrument 10, wherein only the differences compared to the first example embodiment described above are explained hereinafter. For example, the measurement instrument 10 shown in FIG. 2 may be a vector network analyzer.

As shown in FIG. 2, the measurement instrument 10 comprises a directive circuit 18 that is connected to the DUT connector 12. In the example embodiment shown in FIG. 2, the directive circuit 18 comprises the voltage limiter circuit 14 described above. However, it is also conceivable that the directive circuit 18 and the voltage limiter circuit 14 may be established separately from each other.

In an embodiment, the directive circuit 18 comprises a DUT port 20 that is connected to the DUT connector 12 of the measurement instrument 10. Accordingly, the DUT port 20 is connectable to an electronic device under test via the DUT connector 12. It is noted that further components, e.g. amplifiers, attenuators, filters, etc. may be provided between the DUT port 20 and the DUT connector 12. These additional components may be provided separately from the directive circuit 18, for example not on the same substrate.

In an embodiment, the directive circuit 18 further comprises at least one MEAS port that is connected to the measurement circuit 16. In the example embodiment shown in FIG. 2, the directive circuit 18 comprises a first MEAS port 22 and a second MEAS port 24 for performing differential measurements.

In an embodiment, the measurement circuit 16 may comprise further components such as a filter, an analog-to-digital converter, a mixer, etc. These additional components may be provided separately from the directive circuit 18, for example not on the same substrate, and/or may be integrated into the directive circuit 18. For example, the mixer of the measurement circuit 16 may be provided on the same substrate as the directive circuit 18.

In an embodiment, the directive circuit 18 further comprises a REF port 26 that is connected to a reference circuit 28 of the measurement instrument 10. For example, the reference circuit 28 may be a reference receiver. The reference circuit 28 may comprise further components such as a filter, an analog-to-digital converter, a mixer, etc. These additional components may be provided separately from the directive circuit 18, for example not on the same substrate.

In an embodiment, the directive circuit 18 comprises a GEN port 30 that is connected to a generator circuit 32 of the measurement instrument 10. The generator circuit 32 may be or comprise a signal generator, for example a vector signal generator.

In an embodiment, the generator circuit 32 may comprise further components such as a filter, an analog-to-digital converter, a digital-to-analog converter, a mixer, etc. These additional components may be provided separately from the directive circuit 18, for example not on the same substrate.

In general, the directive circuit 18 is configured to selectively forward signals between the DUT port 20, the MEAS ports 22, 24, the REF port 26, and the GEN port 30. The directive circuit 18 comprises directive elements 33 that are configured to selectively forward signals between the DUT port 20, the MEAS ports 22, 24, the REF port 26, and the GEN port 30. For example, the directive elements 33 may comprise one or more directional couplers.

In a certain embodiment, the directive elements 33 may comprise a first directive element that is configured to forward a signal generated by the generator circuit 32 that is received by the GEN port 30 to the DUT port 20 and to the REF port 26. The directive elements 33 may further comprise a second directive element that is configured to forward a signal travelling from the DUT port 20 towards components downstream of the DUT port 20, i.e. towards the other ports 22, 24, 26, 30, to the MEAS ports 22, 24.

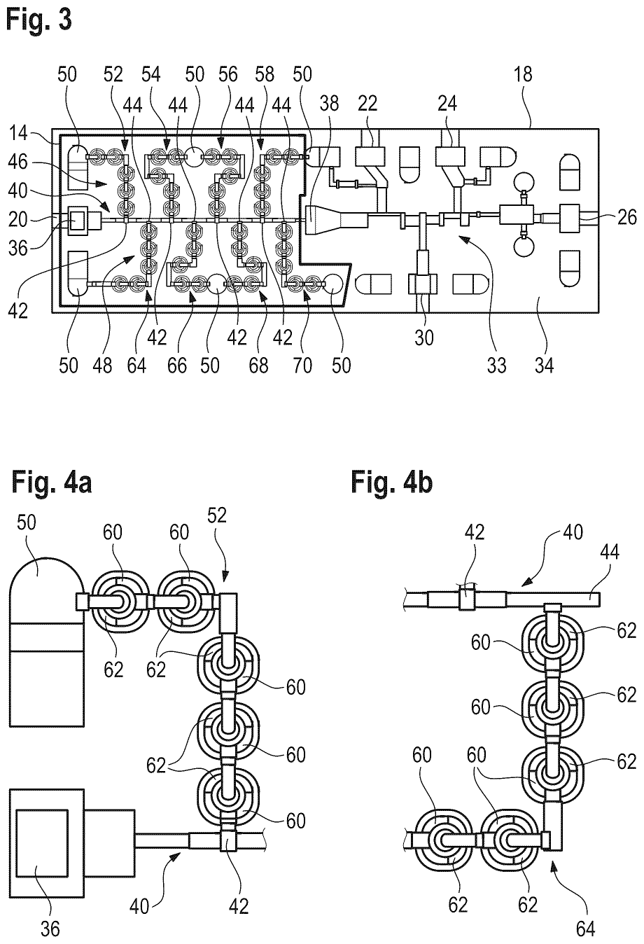

FIG. 3 shows an example of the directive circuit 18 with the voltage limiter circuit 14 in more detail. In an embodiment, the directive circuit 18 may comprise a substrate 34 on which the components described hereinafter are provided. For example, the substrate 34 may comprise or consist of gallium arsenide or another suitable material or combination of materials.

In an embodiment, the directive circuit 18 may be established as a monolithic microwave integrated circuit. Optionally, the directive circuit 18 may comprise a housing that encloses the components of the directive circuit 18.

In the embodiment shown in FIG. 3, the voltage limiter circuit 14 comprises a first port 36 and a second port 38 that are connected with each other by a transmission line 40. The first port 36 may be identical with or connected to the DUT port 20 of the directive circuit 18. The transmission line 40 may be established as a metal stripe that is provided on the substrate 34.

In an embodiment, the transmission line 40 may be a bidirectional transmission line, i.e. signals can be transmitted from the first port 36 to the second port 38 and from the second port 38 to the first port 36 by the transmission line 40. The transmission line 40 comprises a plurality of transmission line sections, wherein neighboring transmission line sections have different impedances.

The different impedances may be caused by the neighboring transmission line sections having different widths, wherein a smaller width corresponds to a larger impedance and a greater width corresponds to a smaller impedance. Without restriction of generality, the example case of the neighboring transmission line sections having different widths is described hereinafter.

In the example embodiment shown in FIG. 3, each transmission line section has one of two different widths and equal length. Accordingly, the transmission line 40 comprises a first type 42 of transmission line sections having a first width and a second type 44 of transmission line sections having a second width, wherein the first width is greater than the second width.

Thus, all transmission line sections of the first type 42 have the same first width, and all transmission line sections of the second type 44 have the same second width. However, it is to be understood that the individual transmission line sections may have more than two different widths and/or different lengths.

In general, the voltage limiter circuit 14 comprises a negative voltage limiter unit 46 that is configured to limit a negative voltage portion on the transmission line 40, as well as a positive voltage limiter unit 48 that is configured to limit a positive voltage portion on the transmission line 40.

The negative voltage limiter unit 46 comprises a plurality of sets of diodes that are interconnected between the transmission line 40 and a respective contact 50 to a first reference potential. In general, the first reference potential may be ground or a constant DC potential, for example a negative voltage.

In an embodiment, the negative voltage limiter unit 46 comprises a first set of diodes 52, a second set of diodes 54, a third set of diodes 56, and a fourth set of diodes 58. In general, the sets of diodes of the negative voltage limiter unit 46 are connected to the transmission line sections of the first type 42, for example to a respective center of the transmission line sections. For example, the first set of diodes 52 is connected to a first transmission line section of the first type 42 that is located closest to the first port 36.

The second set of diodes 54 is connected to a second transmission line section of the first type 42 that is located second-closest to the first port 36 and that is separated from the first transmission line section by one transmission line section of the second type 44. The third set of diodes 56 is connected to a third transmission line section of the first type 42 that is located third-closest to the first port 36 and that is separated from the second transmission line section by one transmission line section of the second type 44. The fourth set of diodes 58 is connected to a fourth transmission line section of the first type 42 that is located closest to the second port 38 and that is separated from the third transmission line section by one transmission line section of the second type 44.

As is illustrated in FIG. 4a for the first set of diodes 52 of the negative voltage limiter unit 46, the individual diodes are arranged in a serial connection between the transmission line 40 and the contact 50. Therein, the cathodes 60 of the individual diodes are facing the transmission line 40, while the anodes 62 of the individual diodes are facing the contact 50. Thus, the cathode 60 of a first one of the diodes is connected to the transmission line 40 directly. The cathode 60 of a second one of the diodes is connected to the anode 62 of the first one of the diodes, etc.

Similarly to the negative voltage limiter unit 46, the positive voltage limiter unit 48 comprises a plurality of sets of diodes that are interconnected between the transmission line 40 and a respective contact 50 to a second reference potential. In general, the second reference potential may be ground or a constant DC potential, for example a positive voltage. In an embodiment, the first reference potential may be equal to the second reference potential. For example, both the first reference potential and the second reference potential may be ground.

However, the first reference potential and the second reference potential may also be different from each other. For example, the first reference potential may be a negative constant DC voltage, while the second reference potential may be a positive constant DC voltage.

In an embodiment, the positive voltage limiter unit 48 comprises a first set of diodes 64, a second set of diodes 66, a third set of diodes 68, and a fourth set of diodes 70. In general, the sets of diodes of the positive voltage limiter unit 48 are connected to the transmission line sections of the second type 44, for example to a respective center of the transmission line sections. For example, the first set of diodes 64 is connected to a first transmission line section of the second type 44 that is located closest to the first port 36.

The second set of diodes 66 is connected to a second transmission line section of the second type 44 that is located second-closest to the first port 36 and that is separated from the first transmission line section by one transmission line section of the first type 42. The third set of diodes 68 is connected to a third transmission line section of the second type 44 that is located third-closest to the first port 36 and that is separated from the second transmission line section by one transmission line section of the first type 42. The fourth set of diodes 70 is connected to a fourth transmission line section of the second type 44 that is located closest to the second port 38 and that is separated from the third transmission line section by one transmission line section of the first type 42.

As is illustrated in FIG. 4b for the first set of diodes 64 of the positive voltage limiter unit 48, the individual diodes are arranged in a serial connection between the transmission line 40 and the contact 50. Therein, the anodes 62 of the individual diodes are facing the transmission line 40, while the cathodes 60 of the individual diodes are facing the contact 50.

Thus, the anode 62 of a first one of the diodes is connected to the transmission line 40 directly. The anode 62 of a second one of the diodes is connected to the cathode 60 of the first one of the diodes, etc.

In the embodiment shown in FIGS. 3, 4a, and 4b, the individual sets of diodes comprise five diodes, respectively. However, it is to be understood that the sets of diodes may comprise any other number of diodes greater than or equal to three.

In an embodiment, the individual diodes may be established as PIN diodes or as another suitable type of diode.

In general, the voltage limiter circuit 14 described above protects all components downstream of the voltage limiter circuit 14, for example the measurement circuit 16, the reference circuit 28, and/or the generator circuit 32 from overvoltages.

Therein, it has turned out that the voltage limiter circuit 14 described above provides improved transmission characteristics over a large frequency band, namely from 0 Hz, i.e. direct current, up to 54 GHz, and can reliably protect the downstream components from electrostatic discharges up to 8 kV.

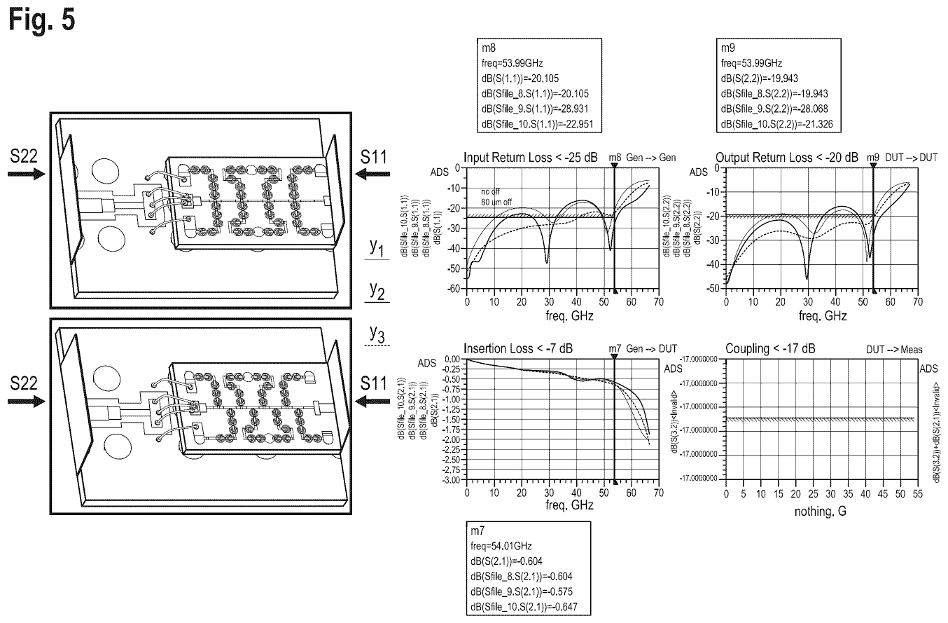

FIG. 5 shows a comparison of different S-parameter plots, wherein y_1 corresponds to the results for a voltage limiter circuit configuration shown in the upper left hand side of FIG. 5, y_3 corresponds to the voltage limiter circuit 14 describe above and shown in the lower left hand side of FIG. 5, and y_2 corresponds to the voltage limiter circuit 14 describe above, but with a constant width of the transmission line 40 between the first port 36 and the second port 38.

As can be seen in FIG. 5, providing the different sets of diodes with different distances from the first port 36 (y_2) already improves the transmission characteristics compared to y_1.

Providing the transmission line sections with alternating widths (y_3) further improves the transmission characteristics, for example wherein resonance modes are flattened such that more uniform transmission characteristics are provided.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more analog or digitally discrete circuit element. For example, circuitry includes hardware circuit implementations (e.g., implementations in analog circuitry, implementations in digital circuitry, and the like, and combinations thereof).

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof.

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

In an embodiment, the functionality described herein can be implemented by special purpose hardware-based circuits, etc., or combinations of special purpose hardware and computer instructions. Each of these special purpose hardware-based circuits, or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. While the stated range includes one or both of the limits, ranges excluding either or both of those included limits are also included in the disclosure

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A voltage limiter circuit for limiting a voltage applied to an electronic structure, comprising
a first port being connectable to a device under test;
a second port being connectable to the electronic structure;
a transmission line connecting the first port and the second port;
positive voltage limiter circuitry configured to limit a positive voltage portion on the transmission line to a threshold, and
negative voltage limiter circuitry configured to limit a negative voltage portion on the transmission line to a threshold.

2. The voltage limiter circuit of claim 1, wherein the transmission line comprises a plurality of transmission line sections, wherein neighboring transmission line sections have different impedances.

3. The voltage limiter circuit of claim 2, wherein the neighboring transmission line sections have different widths.

4. The voltage limiter circuit according to claim 2, wherein all transmission line sections with a smaller impedance compared to neighboring transmission line sections have the same impedance, and/or wherein all transmission line sections with a larger impedance compared to neighboring transmission line sections have the same impedance.

5. The voltage limiter circuit of claim 2, wherein the negative voltage limiter circuitry is connected to the transmission line sections having a smaller impedance compared to neighboring transmission line sections.

6. The voltage limiter circuit of claim 5, wherein the negative voltage limiter circuitry is connected to respective centers of the transmission line sections having the smaller impedance.

7. The voltage limiter circuit according to claim 2, wherein the positive voltage limiter circuitry is connected to the transmission line sections having a larger impedance compared to neighboring transmission line sections.

8. The voltage limiter circuit of claim 7, wherein the positive voltage limiter circuitry is connected to respective centers of the transmission line sections having the larger impedance.

9. The voltage limiter circuit according to claim 5, wherein the negative voltage limiter circuitry comprises a first set of diodes and a second set of diodes, wherein the first set of diodes is interconnected between a first reference potential and a first one of the transmission line sections having the smaller impedance, and wherein the second set of diodes is interconnected between the first reference potential and a second one of the transmission line sections having the smaller impedance.

10. The voltage limiter circuit of claim 9, wherein the first reference potential is ground or a constant DC potential.

11. The voltage limiter circuit of claim 9, wherein cathodes of the first set of diodes and of the second set of diodes are facing the transmission line.

12. The voltage limiter circuit of claim 9, wherein the first set of diodes and the second set of diodes are connected to different transmission line sections.

13. The voltage limiter circuit according to any one of claim 5, wherein the positive voltage limiter circuitry comprises a first set of diodes and a second set of diodes, wherein the first set of diodes is interconnected between a second reference potential and a first one of the transmission line sections having the larger impedance, and wherein the second set of diodes is interconnected between the first reference potential and a second one of the transmission line sections having the larger impedance.

14. The voltage limiter circuit of claim 13, wherein the second reference potential is ground or a constant DC potential.

15. The voltage limiter circuit of claim 13, wherein anodes of the first set of diodes and of the second set of diodes are facing the transmission line.

16. The voltage limiter circuit of claim 13, wherein the first set of diodes and the second set of diodes are connected to different transmission line sections.

17. The voltage limiter circuit according to claim 2, wherein the transmission line sections have equal length.

18. The voltage limiter circuit according to claim 1, wherein the voltage limiter circuit is established as a monolithic microwave integrated circuit.

19. A directive circuit, comprising:
a plurality of ports, wherein the plurality of ports comprise a DUT port and at least two further ports, wherein the DUT port is connectable to a device under test,
wherein the directive circuit is configured to selectively forward signals between the plurality of ports, and wherein the DUT port comprises or is connected to the voltage limiter circuit according to claim 1.

20. A measurement instrument comprising the voltage limiter circuit according to claim 1.
